(19) United States
(12) Patent Application Publication
(10) Pub. No.: US 2020/0080215 A1
(43) Pub. Date: Mar. 12, 2020

(54) A METHOD FOR PREPARING ELECTROPLATING COPPER LAYER WITH PREFERRED GROWTH ORIENTATION

(71) Applicant: Suzhou Shinhao Materials LLC, Suzhou (CN)

(72) Inventors: Yun ZHANG, Suzhou (CN); Zifang ZHU, Suzhou (CN); Tao MA, Wujiang (CN); Luming CHEN, Suzhou (CN); Jing Wang, Suzhou (CN)

(21) Appl. No.: 15/745,695

(22) PCT Filed: Sep. 26, 2017
(86) PCT No.: PCT/CN2017/103500

§ 371 Date: Jan. 17, 2018

(30) Foreign Application Priority Data
Nov. 23, 2016 (CN) 201611037366.1

(51) Int. Cl. C25D 3/38; C25D 7/12; C25D 21/10; C25D 17/10; H01L 23/532; H01L 21/288; H01L 21/768

(52) U.S. Cl. CPC C25D 3/38; C25D 7/123; C25D 21/10; H01L 21/76873; H01L 23/53238; H01L 21/2885; C25D 17/10

(57) ABSTRACT

A method of preparing an electroplating copper layer having a preferred growth orientation includes: providing an electroplating solution that includes 120 to 200 g/L of copper sulfate, 50 to 150 g/L of sulfuric acid, 100 to 1000 ppm of a wetting agent, 5 to 50 ppm of a brightener, 40 to 100 ppm of a non-dye leveler, and water; providing a phosphorous copper anode that includes 0.03-150 wt % of phosphor; and conducting electroplating at a current density of 1-18 A/dm²; and applying mechanical stirring to ensure an uniform concentration distribution of the electroplating solution and to increase mass transfer.

The present invention claims priority to Chinese Patent Application No. 201611037366.1, filed on Nov. 23, 2016, which is incorporated by reference for all purposes as if fully set forth herein.

### FIELD OF THE INVENTION

The present invention relates to the field of electroplating, and in particular to a method of preparing an electroplating copper layer.

### BACKGROUND OF THE INVENTION

Copper has become an excellent material for interconnecting chips due to its excellent electrical and thermal conductivities, low melting point, and good ductility. Copper plating can be used for copper interconnection. Higher I/O count, higher package density, smaller size package structure, more reliable performance and thermal stability, is a major trend in the current semiconductor advanced packaging. Wafer Level Chip Scale Packaging (WLCSP), 3D IC Packaging, and Packaging on Packaging (POP) and other packaging forms, are some examples of this trend.

With the increasing wafer-level packaging density, the sizes of Cu columns and RDL lines are getting smaller. The bonding strength between the Cu columns/RDL Line and the wafer substrate determines the reliability of the chip. In a subsequent copper seed layer removal step, an existing electroplating copper layer inevitably has under-cut defects. When the sizes of the Cu columns and the RDL lines are getting smaller, the presence of udder-cut defects makes the chips easy to loss functions. Thus, there is a reliability problem.

The electroplating copper layer is directly in contact with the sputtered copper seed layer. When the internal structure of the electroplating copper layer is disordered and irregular, the bonding strength to the copper seed layer is weak and the thermal stability is poor, thus leading to reliability problems.

### SUMMARY OF THE INVENTION

In one embodiment, the present invention provides a method of preparing an electroplating copper layer having a preferred growth orientation. The method includes providing an electroplating solution that includes 120 to 200 g/L of copper sulfate, 50 to 150 g/L of sulfuric acid, 100 to 1000 ppm of a wetting agent, 5 to 50 ppm of a brightener, 40 to 100 ppm of a non-dye leveler, and water; providing a phosphorous copper anode that includes 0.03-150 wt % of phosphor; and conducting electroplating at a current density of 1-18 A/dm²; and applying mechanical stirring to ensure an uniform concentration distribution of the electroplating solution and to increase mass transfer.

In another embodiment, the wetting agent is polyethylene glycol, polyethyleneimine, 2-mercaptoethanol, polypropylene ether, or poly N,N′-diethylsaphranin.

In another embodiment, the brightener is an organosulfate having formula (II):

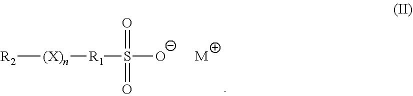

In formula (II), X is O or S; n is 1 to 6; M is hydrogen, alkali metal, or ammonium; R₁ is an alkylene, cyclic alkylene group of 1 to 8 carbon atoms, or an aromatic hydrocarbon of 6 to 12 carbon atoms; and R₂ is MO₃SR₁.

In another embodiment, the organosulfate is sodium lauryl sulfate, disodium 3,3-dithiobispropane-sulphonate, or 3, 3′-dithiobispropanesulfonic acid.

In another embodiment, the non-dye leveler is a quaternary ammonium salt having formula (I):

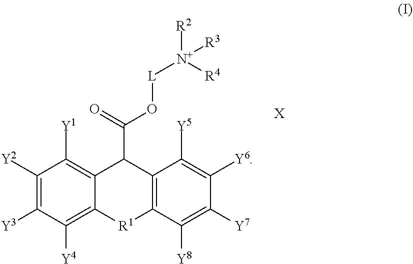

In formula (I), X is Cl⁻, or Br⁻; R¹ is O, S or N; R², R³ and R⁴ are independently selected from the group consisting of hydrogen, unsubstituted or substituted alkyl, unsubstituted or substituted alkenyl, unsubstituted or substituted alkynyl, unsubstituted or substituted C₃₋₁₂cycloalkyl, unsubstituted or substituted C₆₋₁₂ aryl, unsubstituted or substituted 3-12 membered heterocyclic, and unsubstituted or substituted 5-12 membered heteroaryl; or R² and R³ may combine with an atom or atoms to which they are attached to form unsubstituted or substituted C₃₋₁₂cycloalkyl, unsubstituted or substituted 3- to 12-membered heterocyclic, unsubstituted or substituted C₆₋₁₂ aryl, or unsubstituted or substituted 5- to 12-membered heteroaryl; Y¹, Y², Y³, Y⁴, Y⁵, Y⁶, Y⁷, and Y⁸ are independently selected from the group consisting of hydrogen, halogen, unsubstituted or substituted alkyl, unsubstituted or substituted alkenyl, unsubstituted or substituted alkynyl, unsubstituted or substituted C₃₋₁₂cycloalkyl, unsubstituted or substituted C₆₋₁₂ aryl, unsubstituted or substituted 3-12 membered heterocyclic, and unsubstituted or substituted 5-12 membered heteroaryl; and L is selected from the group consisting of unsubstituted or substituted alkyl, unsubstituted or substituted C₆₋₁₂ aryl, and unsubstituted or substituted 3- to 12-membered heterocyclyl.

In another embodiment, the non-dye leveler is

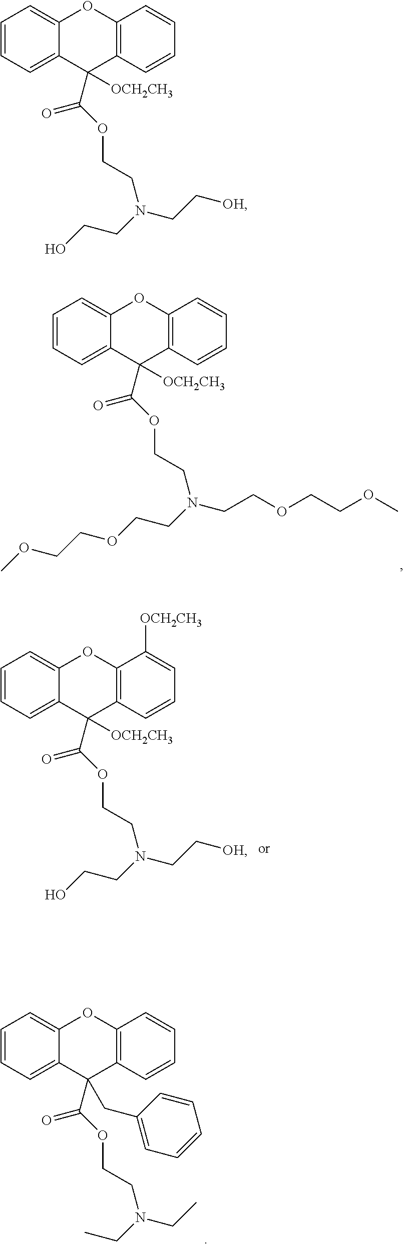

In one embodiment, the present invention provides a copper layer having a Z-axis preferred growth orientation prepared by the method of preparing an electroplating copper layer having a preferred growth orientation described above. The copper layer includes a wafer substrate, an adhesive layer, a copper seed layer, and an electroplated copper layer. The electroplating copper layer includes a bamboo-like crystal structure in the Z-axis preferred growth orientation, and the bamboo-like crystal structure includes larger crystal size and less crystal boundaries in a Z-axis direction than in an X-axis direction.

In another embodiment, the wafer substrate is a silicon or silicon germanium semiconductor substrate, chip or device, and the adhesive layer is a titanium layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 shows a schematic structure of an electroplating copper layer having a preferred Z-axis growth orientation according to an embodiment of the present invention.

FIG. 2 is an FIB picture (5ASD) of an example of the electroplating copper layer having a preferred Z-axis growth orientation according to an embodiment of the present invention.

FIG. 3 is an FIB picture (5ASD) of another example of the electroplating copper layer having a preferred Z-axis growth orientation according to an embodiment of the present invention.

FIG. 4 is an FIB picture (10ASD) of an example of the electroplating copper layer having a preferred Z-axis growth orientation according to an embodiment of the present invention.

FIG. 5 is a schematic flow diagram of a process for measuring the etching rate of an electroplating copper layer according to an embodiment of the present invention.

FIG. 6 is a surface view of an electroplating copper layer having a Z-axis preferential orientation structure after etching according to an embodiment of the present invention.

FIG. 7 is a surface view of an electroplating copper layer after etching, and the electroplating copper layer was prepared by a conventional method (current market leader).

FIG. 8A shows the surface and cross-section hardness of the inventive and comparative electroplating copper layers. FIG. 8B shows the cross-section hardness of the inventive and comparative electroplating copper layers.

FIG. 9A shows the inventive electroplating copper layer having preferred Z-axis growth orientation with less undercut problem. FIG. 9B shows the conventional electroplating copper layer with undercut problem.

FIG. 10 shows the procedure to characterize the surface roughness of the electroplating copper layer.

FIG. 11 shows an etching procedure.

FIG. 12 shows the surface roughness of inventive electroplating copper layer and conventional electroplating copper layer.

FIG. 13 shows the surface roughness of the inventive electroplating copper layer with different plating CD (5 ASD, 10 ASD, and 15 ADS) before and after etching.

### DETAILED DESCRIPTION OF THE ILLUSTRATED EMBODIMENTS

Reference will now be made in detail to embodiments of the present invention, example of which is illustrated in the accompanying drawings.

The present invention provides a method of preparing an electroplating copper layer having a preferred growth orientation and a copper layer having a Z-axis preferred growth orientation prepared by the method.

Compared with conventional electroplating method, the present invention has the following advantages and benefits:

1) The present invention produces an electroplating copper layer having a preferred growth orientation on a wafer substrate. The electroplating copper layer includes a large number of adjacent bamboo-like crystal structures in a Z-axis direction (a direction perpendicular to the wafer substrate). The etching rate along the Z-axis is very slow, and when the copper seed layer is removed, the under-cut defects can be avoided. The reliability for the related products is thus improved.

2) The tensile strength in the Z-axis direction and the bonding strength to the copper seed layer on the wafer substrate becomes very high, thus ensuring the reliability of the copper layer;

3) The hardness in a direction parallel to the Z-axis is high, and the hardness on an X-axis direction (particular to the Z-axis direction) is low. A copper layer with a preferred growoth orientation can be prepared according to the demand;

4) The method of the present invention uses a DC plating process that is compatible with existing wafer-level packaging preparation technology. The DC plating process has a wide current density range, and is suitable for copper interconnection technology, such as Copper Pillar, RDL and UBM.

### Example 1

As shown in FIG. 1, a copper layer having a preferred Z-axis growth orientation includes, in order, a wafer substrate 1, an adhesive layer 2, a copper seed layer 3, and an electroplating copper layer 4. The electroplating copper layer 4 includes a bamboo-like crystal structure in the preferred Z-axis growth orientation, and the bamboo-like crystal structure includes larger crystal size and less crystal boundaries in a Z-axis direction than in an X-axis direction.

The wafer substrate 1 is a silicon or silicon germanium semiconductor material, chip, or device. The adhesive layer 2 is a titanium layer.

The copper seed layer 3 is prepared by magnetron sputtering, and is connected to the electroplating copper layer 4.

### Example 2

A method for preparing an electroplating copper layer having a preferred growth orientation includes providing an electroplating solution that includes 120 to 200 g/L of copper sulfate, 50 to 150 g/L of sulfuric acid, 100 to 1000 ppm of a wetting agent, 5 to 50 ppm of a brightener, 40 to 100 ppm of a non-dye leveler, and water; providing a phosphorous copper anode that includes 0.03-150 wt % of phosphor; and conducting electroplating at a current density of 1-18 A/dm²; and applying mechanical stirring to ensure an uniform concentration distribution of the electroplating solution and to increase mass transfer.

Preferably, the wetting agent is polyethylene glycol, polyethyleneimine, 2-mercaptoethanol, polypropylene ether, or poly N,N′-diethylsaphranin.

Preferably, the non-dye leveler is a quaternary ammonium salt having formula (I):

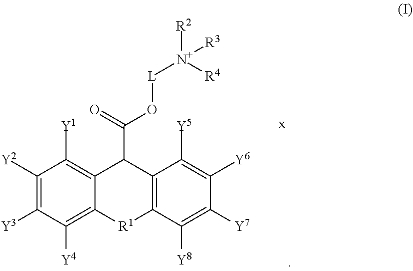

In formula (I), X is Cl⁻, or Br⁻; R¹ is O, S or N; R², R³ and R⁴ are independently selected from the group consisting of hydrogen, unsubstituted or substituted alkyl, unsubstituted or substituted alkenyl, unsubstituted or substituted alkynyl, unsubstituted or substituted C₃₋₁₂cycloalkyl, unsubstituted or substituted C₆₋₁₂ aryl, unsubstituted or substituted 3-12 membered heterocyclic, and unsubstituted or substituted 5-12 membered heteroaryl; or R² and R³ may combine with an atom or atoms to which they are attached to form unsubstituted or substituted C₃₋₁₂cycloalkyl, unsubstituted or substituted 3- to 12-membered heterocyclic, unsubstituted or substituted C₆₋₁₂ aryl, or unsubstituted or substituted 5- to 12-membered heteroaryl; Y¹, Y², Y³, Y⁴, Y⁵, Y⁶, Y⁷, and Y⁸ are independently selected from the group consisting of hydrogen, halogen, unsubstituted or substituted alkyl, unsubstituted or substituted alkenyl, unsubstituted or substituted alkynyl, unsubstituted or substituted C₃₋₁₂cycloalkyl, unsubstituted or substituted C₆₋₁₂ aryl, unsubstituted or substituted 3-12 membered heterocyclic, and unsubstituted or substituted 5-12 membered heteroaryl; and L is selected from the group consisting of unsubstituted or substituted alkyl, unsubstituted or substituted C₆₋₁₂ aryl, and unsubstituted or substituted 3- to 12-membered heterocyclyl.

Preferably, R¹ in formula (I) is O.

Preferably, Y¹, Y², Y³, Y⁴, Y⁵, Y⁶, Y⁷, and Y⁸ in formula (I) are hydrogen.

Preferably, R², R³ and R⁴ in formula (I) are each independently C₁₋₆alkyl.

Preferably, R² in formula (I) is methyl, and R³ and R⁴ in formula (I) are isopropyl.

Preferably, R² and R³ in formula (I) are ethyl, and R⁴ in formula (I) is benzyl.

Preferably, the non-dye leveler is

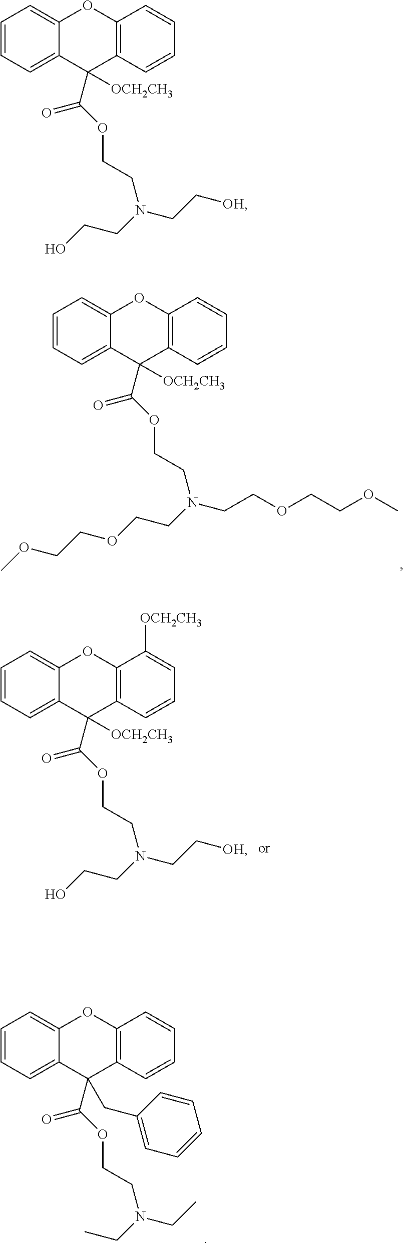

Preferably, the brightener is an organosulfate having formula (II):

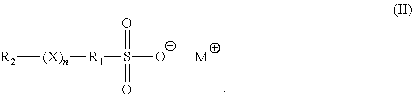

In formula (II), X is O or S; n is 1 to 6; M is hydrogen, alkali metal, or ammonium; R₁ is an alkylene, cyclic alkylene group of 1 to 8 carbon atoms, or an aromatic hydrocarbon of 6 to 12 carbon atoms; and R₂ is MO₃SR₁.

Preferably, X in formula (II) is S.

Preferably, the organosulfate has formula (III):

H₃C—(CH₂)₃—(OC₃H₆)ₘ/(OC₂H₄)ₙ— (III).

In formula (III), n is between 1 and about 200 and m is between 1 and about 200.

Preferably, the organosulfate is sodium lauryl sulfate, disodium 3,3-dithiobi spropane-sulphonate, or 3, 3′-dithiobispropanesulfonic acid.

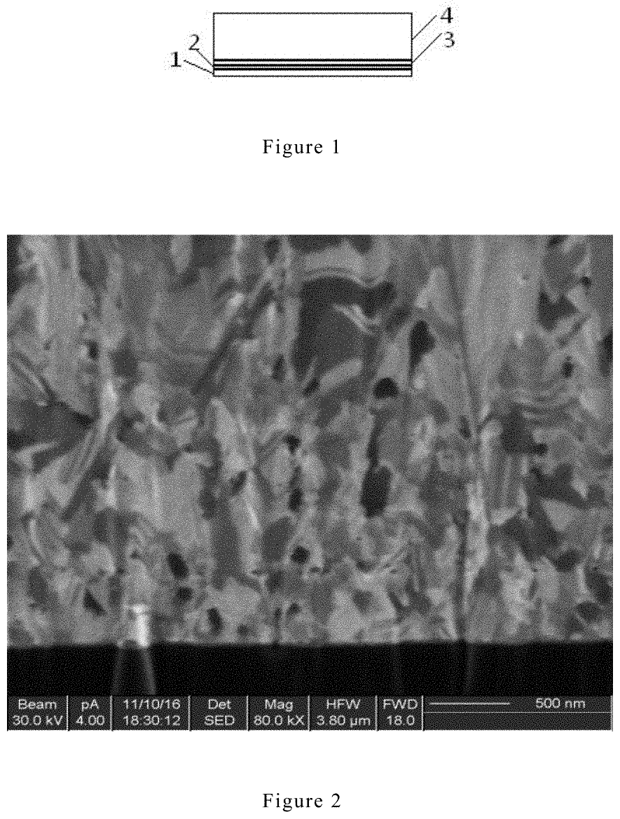

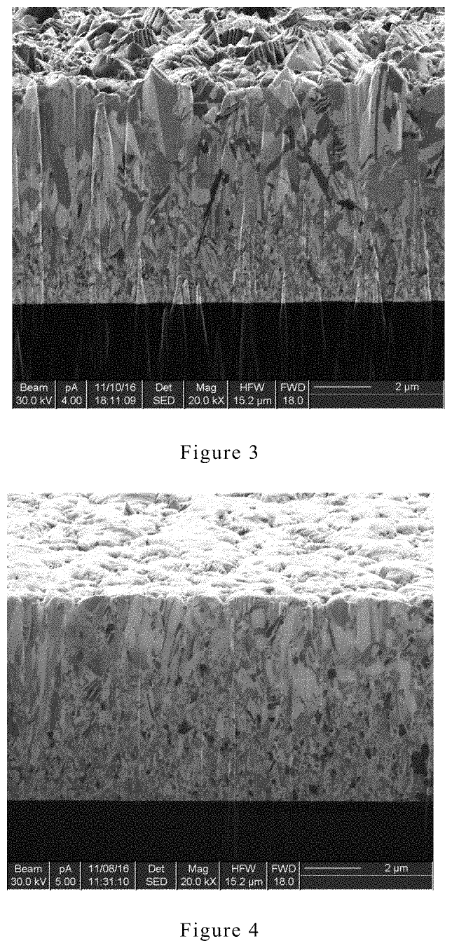

The cross-sectional structure of the electroplating copper layer with preferred Z-axis growth orientation was characterized by FIB (Focused Ion beam). The results are shown in FIGS. 2, 3, and 4.

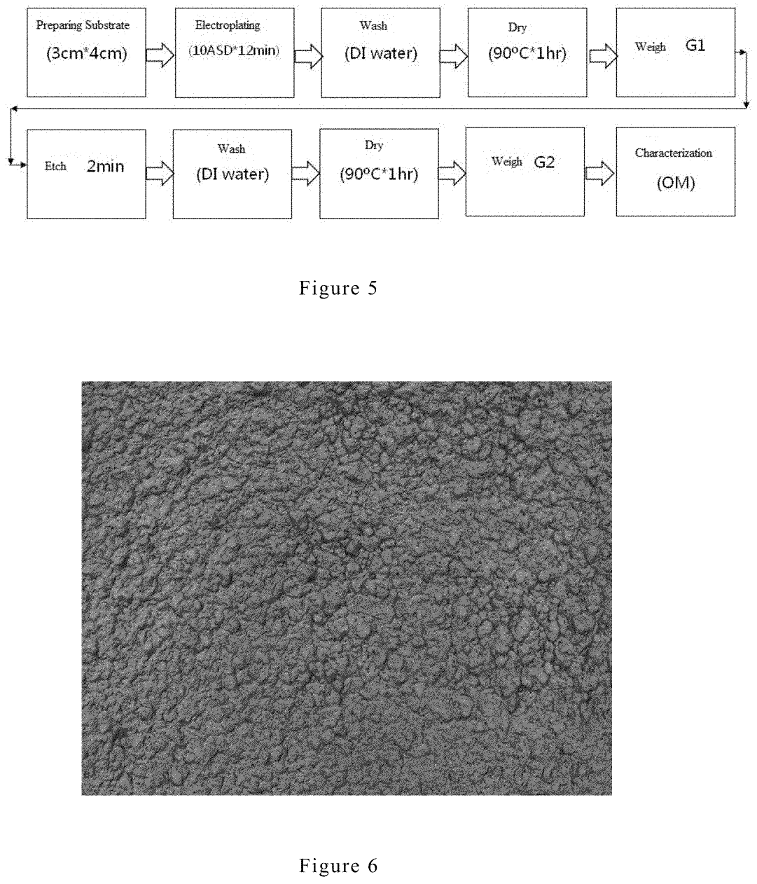

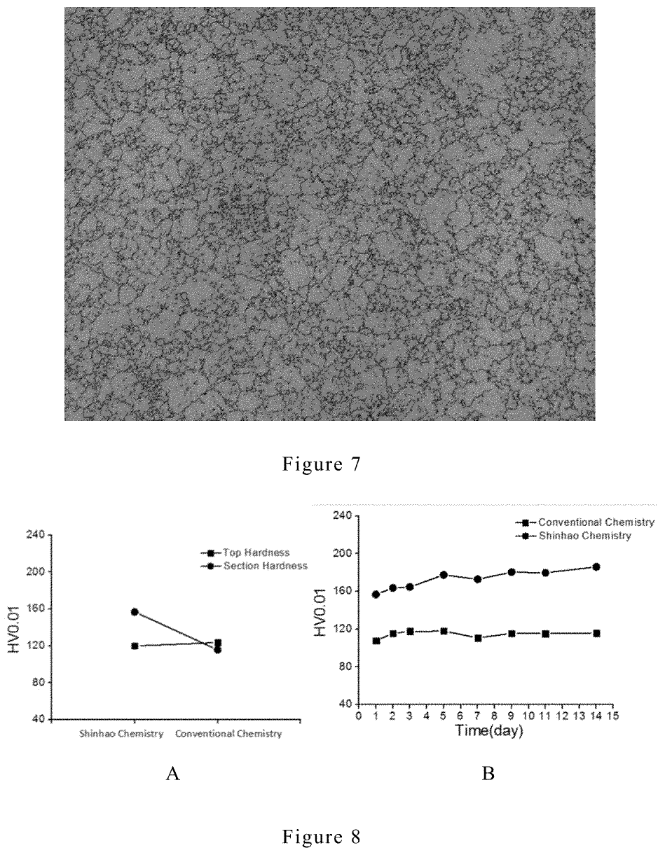

The etching rate of the electroplating copper layer with preferred Z-axis growth orientation is compared with that of a commercially available copper layer from the current Market Leader (Enthone Inc.). The experimental procedure is shown in FIG. 5.

### Example 3

In etching experiments, an electroplating copper layer having preferred Z-axis growth orientation was prepared by using the quaternary ammonium salt, and a conventional electroplating copper layer was prepared by using a plating additive from the current Market Leader. The two electroplating copper layers were subjected to the same condition, and the etching rates were measured. The etching rate of the electroplating copper layer having preferred Z-axis growth orientation is 0.04-0.08 μm/min, preferably, 0.06 μm/min. The etching rate of the conventional electroplating copper layer is 0.13-0.18 μm/min or 0.14 μm/min. The etching rate of the electroplating copper layer having preferred Z-axis growth orientation is much slower than the etching rate of the conventional electroplating copper layer. Accordingly, during the step of removing the copper seed layer, the electroplating copper layer having preferred Z-axis growth orientation has few under-cut defects, and thus has much better reliability than the conventional electroplating copper layer which has more under-cut defects.

### Example 4

The electroplating copper layer having preferred Z-axis growth orientation (Shinhao Chemistry) has a sectional hardness of 156.8HV0.01 and a top surface hardness is 120.1HV0.01, and a difference of the two is 23.46%. The conventional electroplating copper layer (Conventional Chemistry) has a sectional hardness of 115.6HV0.01 and top surface hardness is 123.5HV0.01, and the difference between the two is 7.35%. The results are shown in FIG. 8A (surface and cross-section hardness) and FIG. 8B (cross-section hardness). It is shown that the difference between the sectional hardness and top surface hardness in the electroplating copper layer having preferred Z-axis growth orientation is larger than the difference in conventional electroplating copper layer.

Micro Indenter can be developed into an ex-situ monitoring tool for deposit properties such as hardness. The hardness of our electroplating copper is different when it is measured at different locations. While it is harder perpendicular to its growth direction, its surface hardness is about the same as that from conventional chemistry. The 30% surface-cross section hardness difference can be most logically explained as the result of the anisotropic nature of its microstructure.

### Example 5

Copper pillar plating was carried using the inventive method and conventional method.

Inventive copper electroplating method:

a. Cu²⁺ from copper sulfate (50 g/L, Cu²⁺)

b. Sulfuric acid (100 g/L)

c. Chloride ion (50 ppm)

d. S24 (10 mL/L), L118 (30 mL/L), A28 (4 mL/L)

e. Plating CD: 10 A SD

f. Target height: 50 μm

Conventional copper electroplating method:

a. Cu²⁺ from copper sulfate (50 g/L, Cu²)

b. Sulfuric acid (100 g/L)

c. Chloride ion (50 ppm)

d. A (12 mL/L), B (6 mL/L)

e. Plating CD: 10 ASD

f. Target height: 50 μm

The above-described conditions apply to all the other supplementary copper film properties characterization in this application.

Under cut characterization of the electroplating copper layer having preferred Z-axis growth orientation and the conventional electroplating copper layer was conducted under the following operating conditions:
Etchant: GCT ECU 312
Concentration: Original solution
Temperature: 20-30° C.
Time: 0.5-3 min

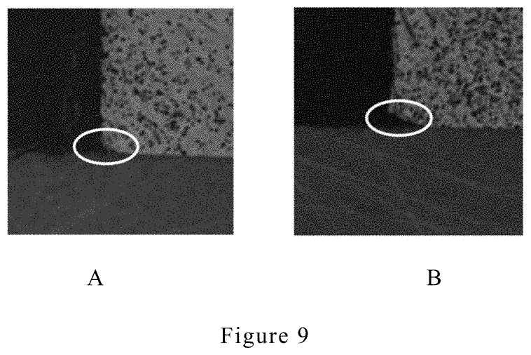

The results are shown in FIG. 9A (the electroplating copper layer having preferred Z-axis growth orientation) and FIG. 9B (the conventional electroplating copper layer). The electroplating copper layer having preferred Z-axis growth orientation has much less undercut problem than the conventional electroplating copper layer, and it is due to the anisotropic microstructures. In addition, the inventive copper electroplating method was carried at high plating speed (i.e. 10 ASD). The inventive method is able to, for the first time, to lower undercut under high plating speed (i.e. 10ASD)

### Example 6

Inter stress of the inventive electroplating copper layer and conventional electroplating copper layer was measured by a stress meter with the following steps: Soak clean, Rinse, Treating with H₂SO₄ 10%, Rinse, Cu Plate, Clean, Dry, and Stress measurement. The results are as follows:

Electroplating copper layer prepared by the inventive method: stable stress 9 MPa, from 0 to 12 hours, and 1 to 15 days.

Electroplating copper layer prepared by the conventional method: stress increasing from 3 MPa to 4.5 MPa from 0 to 12 hours, and stable stress 4.5 MPa from 1 to 15 days.

Stable inter stress indicates that there is no grain size growth with inventive method, while significant inter stress increase in the first few hours suggests grain size change with conventional method.

### Example 7

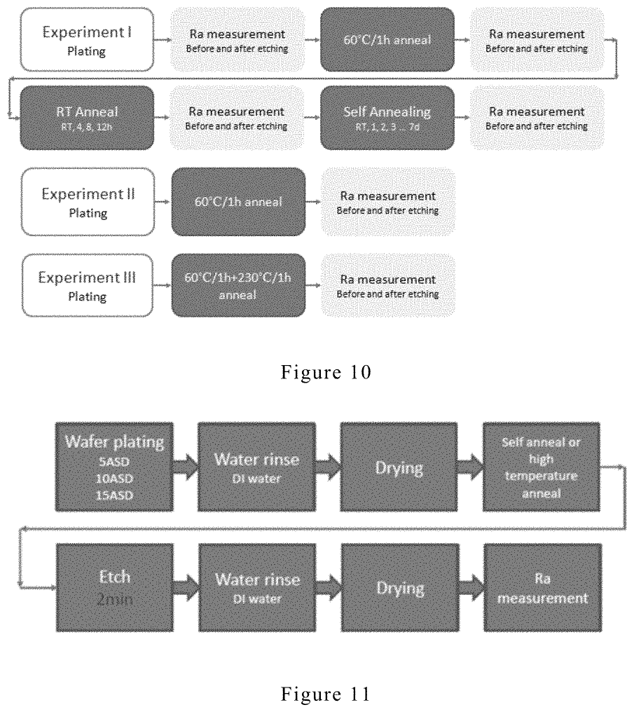

Surface roughness of the electroplating copper layer was characterized with the procedure shown in FIG. 10. Etching procedure is illustrated in FIG. 11.

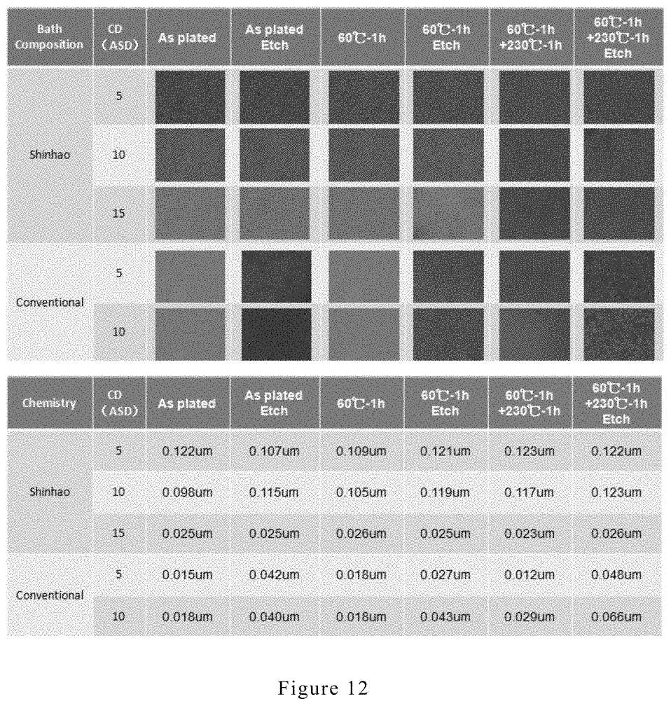

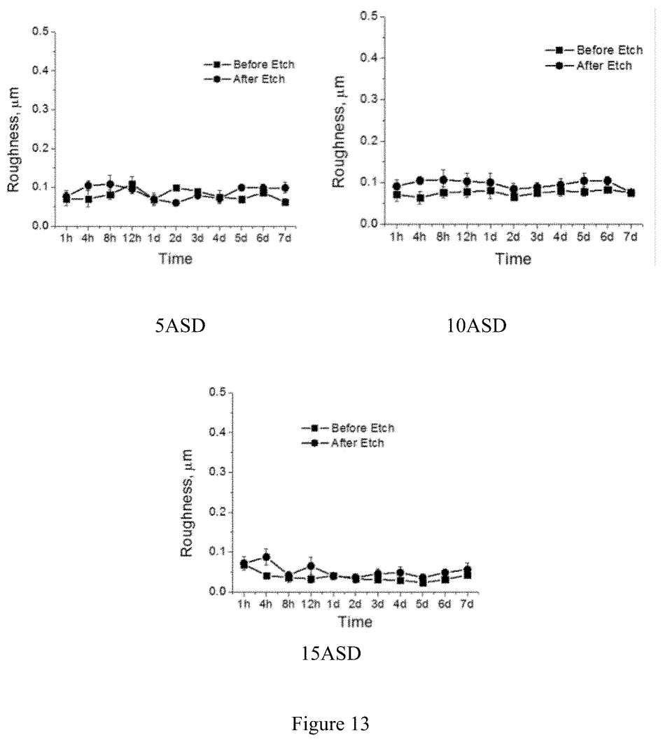

Surface roughness characterization results are shown in FIG. 12 (Shinhao: inventive method). Surface roughness of the inventive electroplating copper layer with different plating CD (5 ASD, 10 ASD, and 15 ADS) before and after etching is shown in FIG. 13.

The surface roughness didn't show significant change for Shinhao chemistry before and after etching, but apparent increase for conventional chemistry. The inventive electroplating copper layer has stable grain size and microstructure. Overall higher roughness than conventional chemistry is due to the anisotropic microstructure.

In addition, there is little change in surface roughness under annealing conditions, which further evidences that the inventive electroplating copper layer has stable microstructure that is tolerant to annealing and etching.

### Example 8

Tensile strength of the electroplating copper layers prepared by inventive method (Shinhao) and conventional method was measured and shown in the Table

TABLE 1
Tensile Strength

| | Shinhao | Conventional |
|---|---|---|
| RT, ld (MPa) | 349.93 | 362.46 |
| RT, 2d (MPa) | 338.93 | 328.46 |
| 230°C., lh (MPa) | 404.72 | 270.61 |

Electroplating copper layer prepared with inventive method showed little tensile strength change during RT self anneal, while 9% tensile strength decrease was observed with that of conventional chemistry. Electroplating copper layer prepared with inventive method showed an increase in tensile strength after 230 C/1 h anneal, ˜49% higher than that of conventional chemistry.

The inventive cross-linked bamboo-like copper layer shows comparable tensile strength with that obtained with conventional chemistry, but the bamboo-like copper layer indicates significantly lower tensile strength decrease during room temperature self anneal.

The tensile strength is increased after thermal anneal due to the enhancement of cross-linking during thermal anneal. While conventional copper shows tensile strength decrease during thermal anneal.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. A method of preparing an electroplating copper layer having a preferred growth orientation comprising:
providing an electroplating solution that includes 120 to 200 g/L of copper sulfate, 50 to 150 g/L of sulfuric acid, 100 to 1000 ppm of a wetting agent, 5 to 50 ppm of a brightener, 40 to 100 ppm of a non-dye leveler, and water;
providing a phosphorous copper anode that includes 0.03-150 wt % of phosphor; and
conducting electroplating at a current density of 1-18 A/dm²; and
applying mechanical stirring to ensure an uniform concentration distribution of the electroplating solution and to increase mass transfer.

2. The method of claim 1, wherein the wetting agent is polyethylene glycol, polyethyleneimine, 2-mercaptoethanol, polypropylene ether, or poly N,N′-diethylsaphranin.

3. The method of claim 1, wherein the brightener is an organosulfate having formula (II): 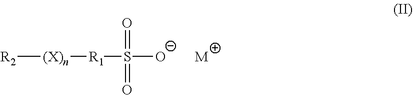
in formula (II), X is O or S; n is 1 to 6; M is hydrogen, alkali metal, or ammonium; R₁ is an alkylene, cyclic alkylene group of 1 to 8 carbon atoms, or an aromatic hydrocarbon of 6 to 12 carbon atoms; and R₂ is MO₃SR₁.

4. The method of claim 3, wherein the organosulfate is sodium lauryl sulfate, disodium 3,3-dithiobispropane-sulphonate, or 3, 3′-dithiobispropanesulfonic acid.

5. (canceled)

6. The method of claim 1, wherein the non-dye leveler is

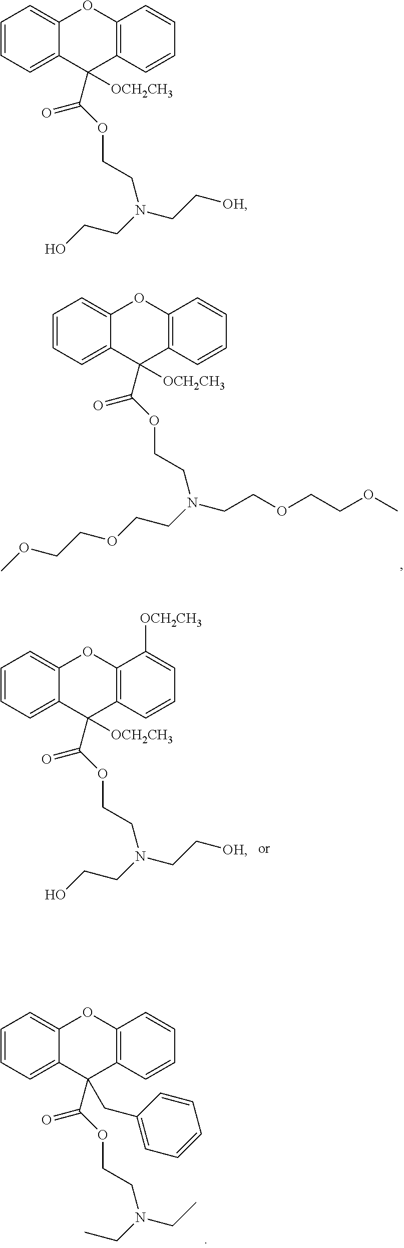

7. A copper layer having a Z-axis preferred growth orientation prepared by the method of claim 1, comprising:
a wafer substrate,
an adhesive layer,
a copper seed layer, and
an electroplated copper layer,
wherein the electroplating copper layer includes a bamboo-like crystal structure in the Z-axis preferred growth orientation, and the bamboo-like crystal structure includes larger crystal size and less crystal boundaries in a Z-axis direction than in an X-axis direction.

8. The copper layer of claim 7, wherein the wafer substrate is a silicon or silicon germanium semiconductor substrate, chip or device, and the adhesive layer is a titanium layer.
